(19) United States
(12) Patent Application Publication
(10) Pub. No.: US 2008/0315188 A1
(43) Pub. Date: Dec. 25, 2008

(54) Apparatus and method for depositing thin film

(76) Inventors: Tae-Hyung Hwang, Seoul (KR); Geun-Young Yeom, Seoul (KR); Chang-Hyun Jeong, Busan-city (KR); June-Hee Lee, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/999,177

(22) Filed: Dec. 3, 2007

(30) Foreign Application Priority Data
Jun. 20, 2007 (KR) 10-2007-0060575

(51) Int. Cl. H01L 51/05; H01J 1/62; H05H 1/24; C23C 16/00

(52) U.S. Cl. 257/40; 313/512; 118/723 E; 427/569; 427/579; 257/E51.006

(57) ABSTRACT

In a thin film depositing apparatus, a first reaction gas, a second reaction gas, and a non-volatile gas are supplied to a reaction chamber in order to form a protective layer, in which an organic layer and an inorganic layer are alternately stacked, on a process substrate. The first reaction gas is supplied to the reaction chamber only while the inorganic layer is formed on the process substrate, and the second reaction gas and the non-volatile gas are supplied to the reaction chamber through while the inorganic and organic layers are formed on the process substrate. Thus, the discontinuous surfaces may be prevented from being formed between the organic layer and the inorganic layer, thereby preventing the peeling of the organic and inorganic layers and increasing light transmittance.

### CROSS-REFERENCE TO RELATED APPLICATION

This application relies for priority upon Korean Patent Application No. 2007-60575 filed on Jun. 20, 2007, the contents of which are herein incorporated by reference in its entirety.

### BACKGROUND OF THE INVENTION

1. Field of the Invention

The present invention relates to an apparatus and method for depositing a thin film and, more particularly, to preventing the separation of a multi-layered protective structure from the thin film.

2. Description of the Related Art

As consumer demand for large-scale and portability of flat panel displays continues to increase, plastic substrates are being more widely employed instead of glass substrates in display devices. Displays using plastic substrate have the advantages of lighter weight, and greater impact resistance bendability and portability. Further, a plastic substrate can be manufactured at lower cost than glass substrates.

However, plastic substrates are more vulnerable to heat so that processes used to manufacture glass substrate flat panel displays cannot be employed to form flat panel displays having plastic substrates. Because a plastic substrate easily transmits oxygen and moisture, electrodes and organic materials are susceptible to being damaged, thereby decreasing the lifespan of the flat panel display.

To prevent such damage of the parts, it has been suggested that a protective multi-layered structure could be formed on the plastic substrate. Such a multi-layered structure includes an inorganic layer blocking the oxygen and moisture and an organic layer planarizing and protecting the plastic substrate from external impacts. However, when the organic layer and the inorganic layer are applied together to the plastic substrate, the organic and inorganic layers separate from each other. Further, the light transmittance of the plastic substrate is lowered because of the space resulting between the organic and inorganic layers.

### SUMMARY OF THE INVENTION

According to one aspect of the present invention, separation of the organic and inorganic layers of the protective film is prevented, thereby improving light transmittance of the display.

The present invention also provides a thin film depositing apparatus that includes a reaction chamber, a high-frequency electrode, a supporting substrate, a power voltage supply, a first reaction gas supply, a second reaction gas supply, and a non-volatile gas supply to form a protective layer in which an organic layer and an inorganic layer are alternately stacked on a process substrate.

The high-frequency electrode is installed inside the reaction chamber to receive high-frequency power, and the supporting substrate is installed inside the reaction chamber and spaced apart from the high-frequency electrode to support the process substrate and receive a bias voltage.

The power voltage supply supplies the high-frequency power and the bias voltage to the high-frequency electrode and the supporting substrate, respectively. The first reaction gas supply supplies a first reaction gas to the reaction chamber only while the inorganic layer is formed on the process substrate. The second reaction gas supply supplies a second reaction gas to the reaction chamber through while the inorganic layer and the organic layer are formed on the process substrate. The non-volatile gas supply supplies a non-volatile gas to the reaction chamber through while the inorganic layer and the organic layer are formed on the process substrate.

In another aspect of the present invention, a thin film depositing method that forms a protective layer in which an organic layer and an inorganic layer are alternately stacked on a process substrate is provided as follows. First, high-frequency power and a bias voltage are applied to a high-frequency electrode and a supporting substrate that are installed inside a reaction chamber, respectively. A first reaction gas, a second reaction gas, and a non-volatile gas are supplied to the reaction chamber. When plasma is induced by the first reaction gas, the second reaction gas, and the non-volatile gas, an inorganic layer is formed on the process substrate. Then, the supply of the first reaction gas is stopped under the plasma state, so that an organic layer is formed on the process substrate.

In another aspect of the present invention, a display apparatus includes a substrate, a protective layer, and a display unit. The protective layer covers an upper surface of the substrate, and has a structure in which an organic layer and an inorganic layer that are alternately stacked at least twice. Also, the protective layer includes a transition layer in which a ratio of an organic material to an inorganic material gradually varies. The display unit is arranged on the protective layer to display an image. The protective layer may cover the display unit.

According to the above, characteristics of the layers deposited on the process substrate is controlled by adjusting the reaction gases provided to the reaction chamber, so that the protective layer in which the organic layer and the inorganic layer are alternately stacked at least twice may be formed. Thus, discontinuous surfaces may be prevented from being formed at between the organic layer and the inorganic layer, thereby preventing the peeling phenomenon of the organic and inorganic layers and increasing the light transmittance.

### BRIEF DESCRIPTION OF THE DRAWINGS

The above and other advantages of the present invention will become readily apparent by reference to the following detailed description when considered in conjunction with the accompanying drawings wherein:

FIG. 1 is a view showing an exemplary embodiment of a thin film depositing apparatus according to the present invention;

FIG. 2 is a sectional view showing a protective layer formed on a process substrate using the thin film depositing apparatus of FIG. 1;

FIG. 3A is an SEM image showing a structure of a protective layer according to the present invention;

FIG. 3B is an SEM image showing a conventional protective layer;

FIG. 4 is a graph diagram showing a composition variation of a protective layer according to a time lapse;

FIG. 5 is a graph diagram showing a light transmittance of a protective layer according to a wavelength;

FIG. 6 is a graph diagram showing a WVTR (water vapor transmission rate) of a protective layer according to a time lapse;

FIG. 7 is a sectional view showing another exemplary embodiment of a display apparatus according to the present invention;

FIG. 8 is a sectional view showing another exemplary embodiment of a display apparatus according to the present invention; and

FIG. 9 is a sectional view showing another exemplary embodiment of a display apparatus according to the present invention.

### DESCRIPTION OF THE EMBODIMENTS

Hereinafter, the present invention will be explained in detail with reference to the accompanying drawings.

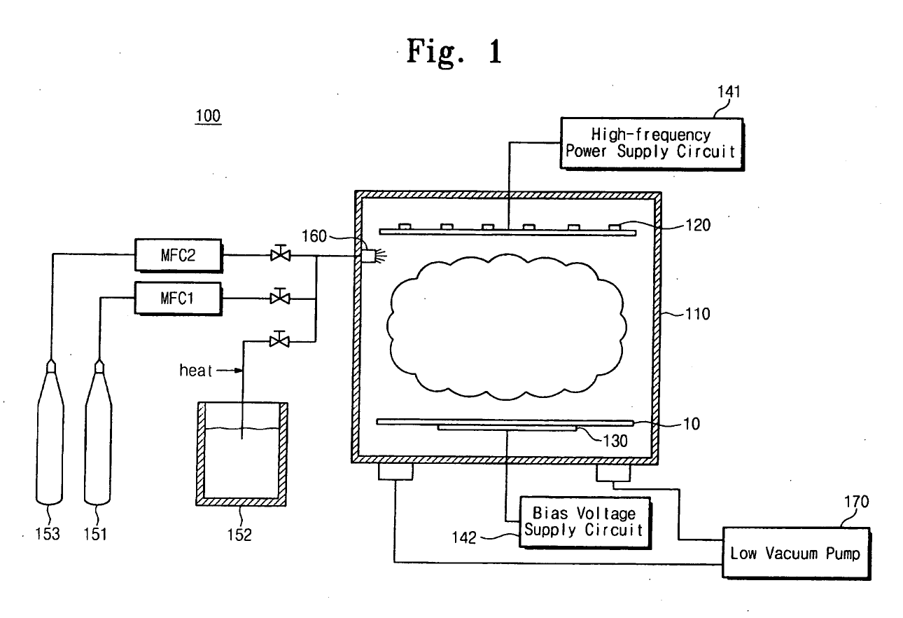

FIG. 1 is a view showing an exemplary embodiment of a thin film depositing apparatus according to the present invention.

Referring to FIG. 1, a thin film depositing apparatus 100 includes a reaction chamber 110, a high-frequency electrode 120, a supporting substrate 130, a high-frequency power supply circuit 141, a bias voltage supply circuit 142, a first reaction gas supply 151, a second reaction gas supply 152, a non-volatile gas supply 153, and a low vacuum pump 170.

The reaction chamber 110 includes a bottom portion, a top portion facing the bottom portion, and a side portion connected between the bottom and top portions to provide a reaction space. The high-frequency electrode 120 and the supporting substrate 130 are installed inside the reaction chamber 110 such that the high-frequency electrode 120 and the supporting substrate 130 are spaced from each other.

More specifically, the high-frequency electrode 120 is positioned adjacent to the top portion of the reaction chamber 110, and the supporting substrate 130 is positioned adjacent to the bottom portion of the reaction chamber 110. In the present exemplary embodiment, the high-frequency electrode 120 is an inductively coupled plasma (ICP) type. The high-frequency electrode 120 receives high-frequency power from the high-frequency power supply circuit 141 installed outside the reaction chamber 110. As an example of the present embodiment, the high-frequency power is in a range from about 50 watts to about 400 watts.

The supporting substrate 130 receives a bias voltage from the bias voltage supply circuit 142 installed outside the reaction chamber 110. In the present exemplary embodiment, the bias voltage applied to the supporting substrate 130 is in a range from about 0 volts to about 300 volts. The supporting substrate 130 fixes the process substrate 10 loaded into the reaction chamber 110 thereto.

The supporting substrate 130 is heated to a predetermined temperature while performing a process. Since the supporting substrate 130 includes a plastic material, the supporting substrate 130 is maintained at a glass transition temperature that does not affect the plastic material. The process temperature in the reaction chamber 110 increases with time. In order to prevent the process temperature from increasing, a coolant is used with the supporting substrate 130. The supporting substrate 130 includes aluminum (Al) having a superior heat conductivity to improve a cooling effect. Thus, the process substrate 10 including the plastic material may be prevented from being affected from the process temperature. Also, the high-frequency electrode 120 is spaced apart from the supporting substrate 130 by about 20 centimeters, so that the process substrate 10 may be prevented from being damaged by heat.

Further, since the thin film depositing apparatus 100 allows the reaction chamber 110 to be maintained at the desired vacuum condition using the low vacuum pump 170, the pumping time to establish the desired vacuum condition may be reduced, thereby reducing a manufacturing cost. Although not shown in FIG. 1, the vacuum pump 170 may include a rotary vain pump and a booster pump.

The first reaction gas supply 151 supplies a first reaction gas to a shower ring 160 installed inside the reaction chamber 110. The first reaction gas provides chemical elements needed to form the inorganic layer on the process substrate 10. In the present exemplary embodiment, the first reaction gas includes nitrous oxide (N₂O) gas.

Further, a first mass flow controller MFC1 is installed at a first gas supply line through which the nitrous oxide N₂O gas is flown to control a flow amount of the N₂O gas flowing through the first gas supply line. The N₂O gas supplied to the reaction chamber 110 has a flow amount of about 0 sccm to about 30 sccm. When the flow amount of N₂O gas is small, density of molecules for the inorganic layer decreases, so that the inorganic layer loses inherent properties thereof. In contrast, when the flow amount of N₂O gas becomes larger than 30 sccm, O—H bonding is increased, thereby causing roughness on the surface of the inorganic layer. Thus, it is preferred that the flow amount of N₂O gas is maintained in a range from about 0 sccm to about 30 sccm.

The second reaction gas supply 152 includes a water bath and a reaction material which is liquid in the water bath. The second reaction gas supply 152 heats a supply line when the reaction material flows through the supply line, so that the second reaction gas is provided to the shower ring 160. The second reaction gas provides chemical elements needed to form the organic layer on the process substrate 10. In the present exemplary embodiment, the second reaction gas includes hexamethyldisilazane (HMDS), and the water bath is filled with the HDMS which is liquid.

In the present exemplary embodiment, the HMDS gas provided to the reaction chamber 110 has a flow amount of about 1 sccm to about 10 sccm. When the flow amount of the HMDS becomes large, contents of carbon and hydrogen increase, so that the light transmittance is deteriorated and particles occur. Thus, it is preferred that the HMDS has the flow amount of about 1 sccm to about 10 sccm.

The non-volatile gas supply 153 provides a non-volatile gas to the shower ring 160. The non-volatile gas is not directly participating in the reaction for the organic and inorganic layers, but the non-volatile gas activates plasma and collides with other substances in the plasma to grow the organic and inorganic layers. As an example of the present invention, the non-volatile gas includes argon (Ar) gas.

Also, a second mass flow controller MFC2 is installed at a second gas supply line through which the argon gas is flown to control a flow amount of the argon gas flowing through the second gas supply line. The argon gas supplied to the reaction chamber 110 has a flow amount of about 0 sccm to about 100 sccm. When the flow amount of the argon gas becomes larger than 100 sccm, the number of neutral particles increases, thereby lowering reaction efficiency. Thus, it is preferred that the flow amount of the argon gas is maintained in a range equal to or smaller than 100 sccm.

The shower ring 160 receives the argon gas, the N₂O gas, and the HMDS gas from the non-volatile gas supply 153, the first reaction gas supply 151, and the second reaction gas supply 152, respectively, and sprays the gases into the reaction chamber 110.

When depositing the inorganic layer, the non-volatile gas supply 153, the first reaction gas supply 151, and the second reaction gas supply 152 provide the argon gas, the N₂O gas, and the HMDS gas to the shower ring 160, respectively. In the present exemplary embodiment, a ratio of the flow amount of the N₂O gas to the HMDS gas is in 1:1 to 1:5 when depositing the inorganic layer. In contrast, when depositing the organic layer, the depositing process for the organic layer is performed using only the HMDS gas and the argon gas after stopping the supply of the N₂O gas to the reaction chamber 110.

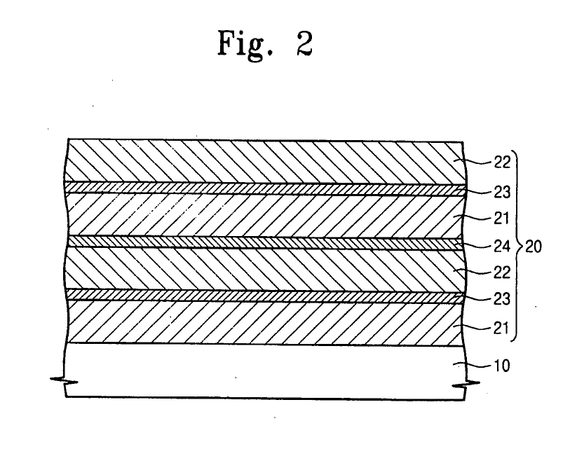

FIG. 2 is a sectional view showing a protective layer formed on a process substrate using the thin film depositing apparatus of FIG. 1.

Referring to FIG. 2, the organic layer 21 and the inorganic layer 22 are alternately formed on the process substrate 10, so that the protective layer 20 having a multi-layered structure is completed. Hereinafter, a process that forms the protective layer will be described.

The high-frequency power is applied to the high-frequency electrode 120, and the HMDS gas and the argon gas are injected inside the reaction chamber 110. The high-frequency electrode 120 reacts with the argon gas to form the plasma between the high-frequency electrode 120 and the supporting substrate 130. In the plasma state, a first organic layer is formed on the process substrate 10 due to reaction of the HMDS gas. In this process, the HMDS gas is analyzed in the plasma and rebonded with carbon (C), hydrogen (H) and nitride (N) to form an organic complex. As an example of the present invention, the organic layer 21 has a composition of SiOx(CH)yNz.

Then, in order to form the inorganic layer 22, the N₂O gas is supplied to the reaction chamber 110 after forming the plasma inside the reaction chamber 110. According to increase of the N₂O gas provided to the reaction chamber 110, a first transition layer 23 is formed on the organic layer 21, in which a ratio of the inorganic material to the organic material gradually increases.

When the ratio of the N₂O gas to a total amount of gases inside the reaction chamber 110 becomes larger than a ratio of the HMDS gas to the total amount of the gases inside the reaction chamber 110, the inorganic layer 22 is formed on the transition layer 23. In other words, in the plasma state, the N₂O gas is analyzed into N and O, and N and O are bonded with Si, C, N, and H generated while analyzing the HMDS gas. In this process, various chemical bonds will be formed, such as Si—O, Si—C, Si—N, Si—H, N—H, C—H, etc. Mainly, a chemical reaction that forms Si—O bond occurs since Si—O bond has a higher energy bond than others. Thus, the inorganic layer 22 having a composition of SiO₂ is formed on the process substrate 10.

Next, the N₂O gas is stopped not to be supplied to the reaction chamber 110 in order to form a second organic layer 21 on the process substrate 10. When the ratio of the N₂O gas to the total amount of the gases inside the reaction chamber 110 decreases by stopping the supply of the N₂O gas, a second transition layer 24 is formed on the inorganic layer 22, in which the ratio of the inorganic material to the organic material gradually decreases.

Then, the second organic layer 21 and a second inorganic layer 22 are further formed on the second transition layer 24 through the forming processes for the organic and inorganic layers 21 and 22. Consequently, the protective layer 20 on which the organic layer 21 and the inorganic layer 22 are sequentially stacked is completed.

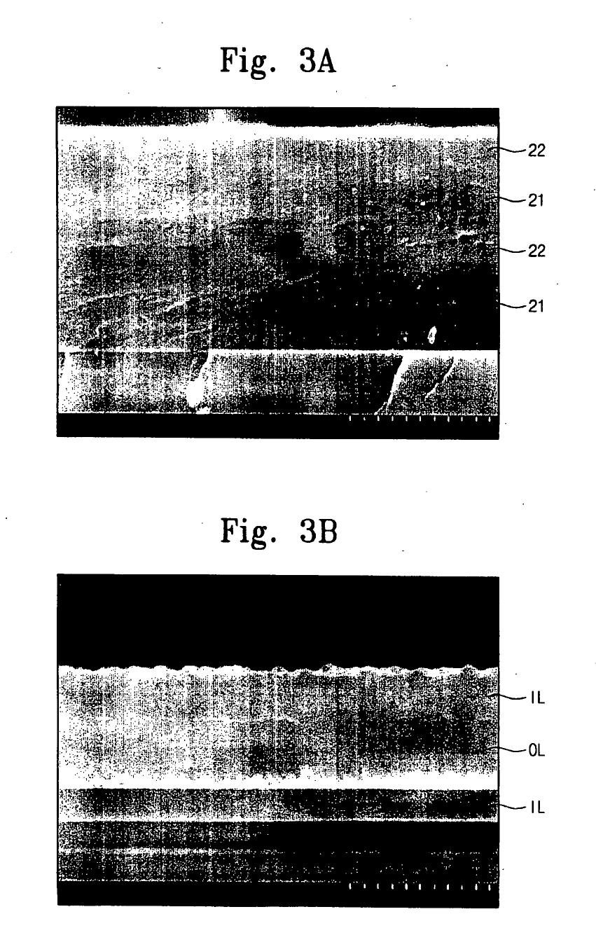

FIG. 3A is an SEM image showing a structure of a protective layer according to the present invention, and FIG. 3B is an SEM image showing a conventional protective layer.

Referring to FIGS. 2 and 3A, the protective layer 20 has a layered structure in the order of the organic layer 21, the inorganic layer 22, the organic layer 21, and the inorganic layer 22. According to the protective layer 20, the first transition layer 23 is formed at a boundary between the organic and inorganic layers 21 and 22, at which the organic layer 21 is formed under the inorganic layer 22. Also, the second transition layer 24 is formed at a boundary between the inorganic and organic layers 22 and 21, at which the inorganic layer 22 is formed under the organic layer 21. Since the ratio of the inorganic material to the organic material gradually varies in each of the first and second transition layers 23 and 24, discontinuous surfaces are not shown at the boundaries between the organic and inorganic layers 21 and 22 and between the inorganic and organic layers 22 and 21.

However, referring to FIG. 3B, in a conventional protective layer, the discontinuous surfaces have been shown at the boundaries between the organic and inorganic layer 21 and 22. That is, since the organic layer and the inorganic layer in the conventional protective layer are deposited through separate processes, respectively, the discontinuous surfaces are generated, thereby causing the peeling of the organic and inorganic layers and deteriorating the light transmittance of the protective layer.

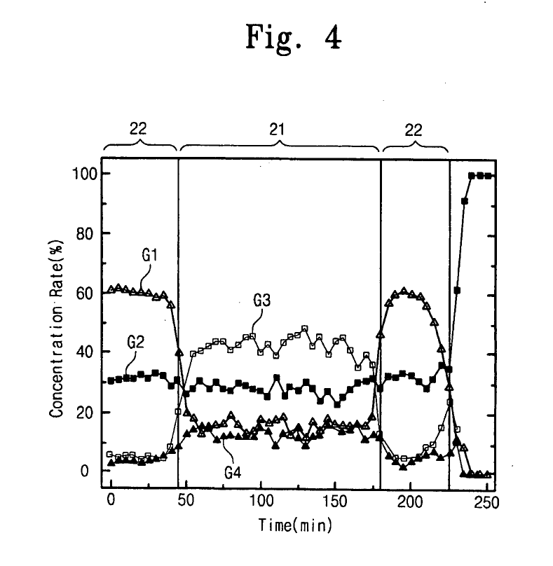

FIG. 4 is a graph diagram showing a composition variation of a protective layer according to a time lapse.

In FIG. 4, a first graph G1 shows a concentration rate of oxygen atoms (O), a second graph G2 shows a concentration rate of silicon atoms (Si), a third graph G3 shows a concentration rate of carbon atoms (C), and a fourth graph G4 shows a concentration rate of nitrogen atoms (N).

Referring to FIGS. 2 and 4, the concentration rate of the oxygen atoms (O) has been shown to be high when the inorganic layer 22 of the protective layer 20 is formed, and then the concentration rate decreases in the order of the silicon atoms (Si), the carbon atoms (C), and the nitrogen atoms (N).

The concentration rate of the oxygen atoms (O) gradually decreases at the boundary between the inorganic layer 22 and the organic layer 21, at which the inorganic layer 22 is transited to the organic layer 21, but the concentration rate of the carbon atoms (C) gradually increases. Then, the concentration rate of the carbon atoms (C) has been shown to be high when the organic layer 21 is formed, and the concentration rate decreases in the order of the silicon atoms (Si), the oxygen atoms (O), and the nitrogen atoms (N).

Next, the concentration rate of the oxygen atoms (O) gradually increases at the boundary between the organic layer 21 and the inorganic layer 22, at which the organic layer 21 is transited to the inorganic layer 22, but the concentration rate of the carbon atoms (C) gradually decreases.

As described above, the concentration rates of the atoms decreases or increases at the boundaries between the organic and inorganic layers 21 and 22, so that the discontinuous surfaces may be prevented from being formed at between the organic and inorganic layers 21 and 22.

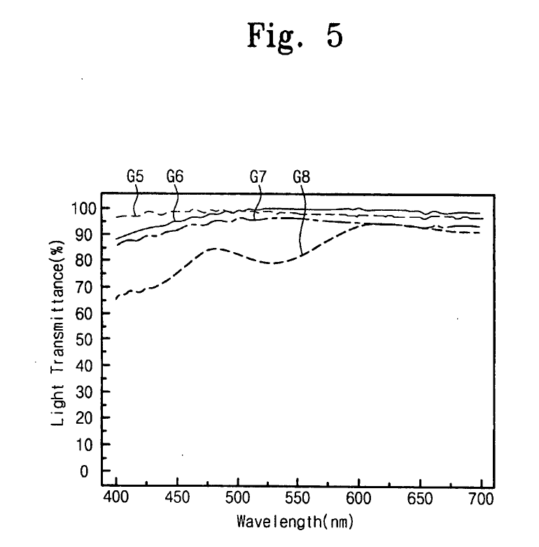

FIG. 5 is a graph diagram showing a light transmittance of a protective layer according to a wavelength.

In FIG. 5, fifth and seventh graphs G5 and G7 represent a light transmittance according to a wavelength of the protective layer of the present invention, and sixth and eighth graphs G6 and G8 represent a light transmittance according to a wavelength of the conventional protective layer. Also, the fifth and sixth graphs G5 and G6 represent the light transmittance in case that the organic and inorganic layers are alternately stacked one on another, and the seventh and eighth graphs G7 and G8 represent the light transmittance in case that two organic layers and two organic layers are alternately stacked one above the other.

Referring to FIG. 5, in the conventional protective layer in which the discontinuous surfaces are formed, the light transmittance is remarkably changed according to the wavelength, and is in a range of about 60% to about 95%. However, in the protective layer in which the discontinuous surfaces are not formed, the light transmittance does not depend on the wavelength, and is in a range of about 85% to about 100%.

That is, the protective layer 20 formed through the deposition method illustrated in FIG. 1 may be free from the peeling phenomenon and have improved light transmittance.

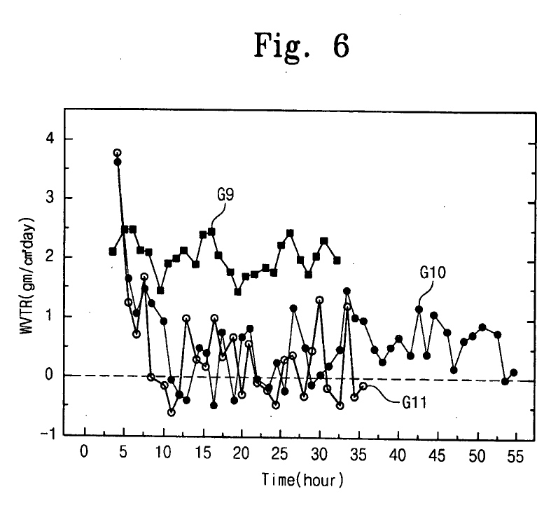

FIG. 6 is a graph diagram showing a water vapor transmission rate (WVTR) of a protective layer according to a time lapse.

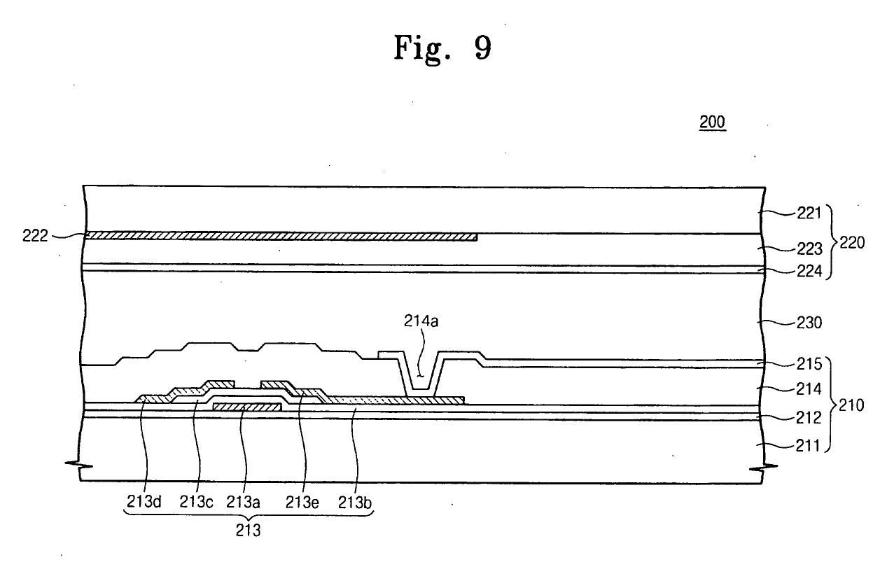

In FIG. 9, a ninth graph G9 represents the WVTR of the protective layer having a layered structure in which the organic and inorganic layers are alternately formed once, a tenth graph G10 represents the WVTR of the protective layer having a layered structure in which the organic and inorganic layers are alternately formed twice, and a eleventh graph G11 represents the WVTR of the protective layer having a layered structure in which the organic and inorganic layers are alternately formed three times.

Referring to FIG. 6, the protective layer in which the organic and inorganic layers are alternately formed once has the WVTR in a range from about 1.5 to about 2.5. However, the protective layer in which the organic and inorganic layers are alternately formed twice or three times has the WVRT in a range from about −0.5 to about 1. Consequently, the WVTR of the protective layer is lowered as the organic and inorganic layers are alternately and repeatedly stacked one on another. Thus, it is preferred that the protective layer has a layered structure in which the organic and inorganic layers are alternately and repeatedly stacked at least twice.

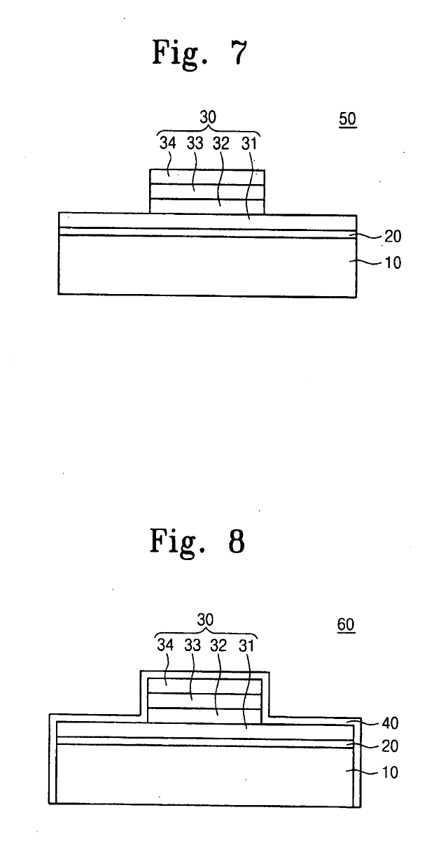

FIG. 7 is a sectional view showing another exemplary embodiment of a display apparatus according to the present invention.

Referring to FIG. 7, a display apparatus 50 includes a substrate 10, a first protective layer 20 arranged on the substrate 10, and an electroluminance display device 30 arranged on the first protective layer 20. The substrate 10 includes a plastic material, and the first protective layer 20 arranged between the substrate 10 and the electroluminance display device 30 blocks the oxygen and moisture from being transmitted to the electroluminance display device 30 through the substrate 10. The first protective layer 20 has the multi-layered structure that the organic 15 layer and the inorganic layer are alternately stacked at least twice.

Since the sectional structure of the first protective layer 20 has been described in detail with reference to FIGS. 1 and 2, the detailed description of the first protective layer 20 will be omitted in FIG. 7.

The electroluminance display device 30 includes a positive electrode layer 31 using a transparent conductive material. As an example of the present invention, the positive electrode layer 31 may include indium tin oxide (ITO). A hole injection layer 32 and an electroluminance layer 33 are sequentially formed on the positive electrode layer 31, and a negative electrode layer 34 is formed on the electroluminance layer 33.

When voltages are applied to the positive electrode layer 31 and the negative electrode layer 34, respectively, the display apparatus 50 displays images using the electroluminance layer 33 having self-emissive characteristics caused by an electric field induced between the positive and negative electrode layers 31 and 34.

FIG. 8 is a sectional view showing another exemplary embodiment of a display apparatus according to the present invention. In FIG. 8, the same reference numerals denote the same elements in FIG. 7, and thus the detailed descriptions of the same elements will be omitted.

Referring to FIG. 8, a display apparatus 60 further includes a second protective layer 40 that is arranged on the substrate 10 to cover the electroluminance display device 30. Although not shown in FIG. 8, the second protective layer 40 has the multi-layered structure where the organic layer and the inorganic layer are alternately stacked at least twice as the first protective layer 20.

The first protective layer 20 blocks the oxygen and the moisture from being transmitted to the electroluminance display device 30 through the substrate 10, and the second protective layer 40 prevents the oxygen and the moisture from being directly transmitted to the electroluminance display device 30 from an exterior.

Thus, the electrodes and the organic materials of the electroluminance display device 30 may be prevented from being damaged by the oxygen and the moisture, thereby increasing the lifespan of the display apparatus 60.

FIG. 9 is a sectional view showing another exemplary embodiment of a display apparatus according to the present invention.

Referring to FIG. 9, a liquid crystal display 200 includes a first substrate 210 in which an organic thin-film transistor 213 is formed, a second substrate 220 facing the first substrate 210 while coupling with the first substrate 210, and a liquid crystal layer 230 interposed between the first substrate 210 and the second substrate 220.

The first substrate 210 includes a first base substrate 211, a first protective layer 212, the organic thin-film transistor 213, a second protective layer 214, and a pixel electrode 215. The first base substrate 211 includes the plastic material having light weight and thin thickness. The first protective layer 212 covers over an upper surface of the first base substrate 211, and the organic thin-film transistor 213 is arranged on the first protective layer 212. Since the first base substrate 211 includes the plastic material having the high WVTR, the first protective layer 212 arranged on the first base substrate 211 prevents the moisture from being transmitted to the organic thin-film transistor 213 through the first base substrate 211.

The first protective layer 212 has the multi-layered structure in which the organic layer and the inorganic layer are alternately stacked at least twice. The first protective layer 212 has the same structure as the protective layer 20 shown in FIG. 2, so the detailed description of the structure of the first protective layer 212 will be omitted in FIG. 9.

The organic thin-film transistor 213 includes a gate electrode 213a that is arranged on the first protective layer 212, a gate insulating layer 213b that covers the gate electrode 213a, a semiconductor layer 213c that is arranged on the gate insulating layer 213b, a source electrode 213d that is arranged on the semiconductor layer 213c, and a drain electrode 213e that is arranged on the semiconductor layer 213c and spaced apart from the source electrode 213d. The semiconductor layer 213c includes a low-molecular weight material, such as a pentacene, in lieu of the silicon. Thin film processes may be readily performed in case of the organic material compared with the silicon, and the organic material has superior flexibility and conductivity, so that the organic thin-film transistor 213 is widely used to the liquid crystal display 200.

The second protective layer 214 includes the organic or inorganic layer to cover the organic thin-film transistor 213. The second protective layer 214 is provided with a contact hole 214a formed therethrough to expose the drain electrode 213e of the organic thin-film transistor 213. The pixel electrode 215 includes the transparent conductive material and is arranged on the second protective layer 214. The pixel electrode 215 is electrically connected to the drain electrode 213e through the contact hole 214a.

The second substrate 220 includes a second base substrate 221, a black matrix 222, a color filter layer 223, and a common electrode 224. The second base substrate 221 is coupled with the first base substrate 211 and faces the first base substrate 211. The black matrix 222 includes an organic or metallic material to prevent leakage of a light through a non-effective display area of the liquid crystal display 200. The color filter layer 223 includes red, green and blue color pixels and is arranged on the second base substrate 221. The common electrode 224 includes the transparent conductive material and is arranged on the color filter layer 223. The common electrode 224 faces the pixel electrode 215 arranged on the first substrate 210 while interposing the liquid crystal layer 230 therebetween. Thus, the light transmittance of the liquid crystal layer 230 is adjusted by an electric field formed between the pixel electrode 215 and the common electrode 224, so that the liquid crystal display 200 may display desired images.

As described above, the first protective layer 212 is arranged on the first base substrate 211 when the first base substrate 211 includes the plastic material having the high WVTR, so that the moisture may be prevented from being transmitted to the organic thin-film transistor 213. Thus, the organic thin-film transistor 213 may be prevented from being damaged by the oxygen and the moisture, thereby increasing the lifespan of the organic thin-film transistor 213.

According to the above, characteristics of the layers deposited on the process substrate is controlled by adjusting the reaction gases provided to the reaction chamber, so that the protective layer in which the organic layer and the inorganic layer are alternately stacked at least twice may be formed.

Thus, the discontinuous surfaces may be prevented from being formed at between the organic layer and the inorganic layer, thereby preventing the peeling phenomenon of the organic and inorganic layers and increasing the light transmittance.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A thin film depositing apparatus that forms a protective layer in which an organic layer and an inorganic layer are alternately stacked on a process substrate, the apparatus comprising:
a reaction chamber;
a high-frequency electrode installed inside the reaction chamber to receive a high-frequency power;
a supporting substrate installed inside the reaction chamber and spaced apart from the high-frequency electrode to support the process substrate and receive a bias voltage;
a power voltage supply supplying the high-frequency power and the bias voltage to the high-frequency electrode and the supporting substrate, respectively;
a first reaction gas supply supplying a first reaction gas to the reaction chamber only while the inorganic layer is formed on the process substrate;
a second reaction gas supply supplying a second reaction gas to the reaction chamber through while the inorganic layer and the organic layer are formed on the process substrate; and
a non-volatile gas supply supplying a non-volatile gas to the reaction chamber through while the inorganic layer and the organic layer are formed on the process substrate.

2. The apparatus of claim 1, wherein the first reaction gas comprises N₂O, and the second reaction gas comprises hexamethyldisilazane (HMDS) gas.

3. The apparatus of claim 2, wherein the non-volatile gas comprises an argon gas.

4. The apparatus of claim 3, wherein the HMDS gas supplied to the reaction chamber has a flow amount of about 1 sccm to about 10 sccm, the N₂O gas supplied to the reaction chamber has a flow amount of about 0 sccm to about 30 sccm, and the argon gas supplied to the reaction chamber has a flow amount of about 0 sccm to about 100 sccm.

5. The apparatus of claim 1, wherein the high-frequency electrode is an inductively coupled plasma (ICP) type.

6. The apparatus of claim 5, wherein the supporting substrate comprises aluminum, and the supporting substrate and the high-frequency electrode are spaced apart from each other by about 20 centimeters.

7. The apparatus of claim 5, wherein the high-frequency power applied to the high-frequency electrode is in a range of about 50 watts to about 400 watts, and the bias voltage applied to the supporting substrate is in a range of about 0 volts to about 300 volts.

8. The apparatus of claim 1, further comprising a vacuum pump that allows the reaction chamber to be maintained in a vacuum condition.

9. A thin film depositing method that forms a protective layer in which an organic layer and an inorganic layer are alternately stacked on a process substrate, the method comprising:
applying a high-frequency power and a bias voltage to a high-frequency electrode and a supporting substrate that are installed inside a reaction chamber, respectively;
supplying a first reaction gas, a second reaction gas, and a non-volatile gas to the reaction chamber to form an inorganic layer on the process substrate using a plasma induced by the first reaction gas, the second reaction gas, and the non-volatile gas; and
stopping the supply of the first reaction gas under the plasma state to form an organic layer on the process substrate.

10. The method of claim 9, wherein the first reaction gas comprises N₂O, the second reaction gas comprises hexamethyldisilazane (HMDS) gas, and the non-volatile gas comprises an argon gas.

11. The method of claim 10, wherein the HMDS gas supplied to the reaction chamber has a flow amount of about 1 sccm to about 10 sccm, the N₂O gas supplied to the reaction chamber has a flow amount of about 0 sccm to about 30 sccm, and the argon gas supplied to the reaction chamber has a flow amount of about 0 sccm to about 100 sccm.

12. The method of claim 9, wherein the high-frequency power applied to the high-frequency electrode is in a range of about 50 watts to about 400 watts, and the bias voltage applied to the supporting substrate is in a range of about 0 volts to about 300 volts.

13. The method of claim 9, wherein the inorganic layer comprises a composition of SiO₂, and the organic layer comprises a composition of SiOx(CH)yNz.

14. The method of claim 9, wherein the process substrate comprises a plastic material.

15. A display apparatus comprising:
a substrate;
a first protective layer covering an upper surface of the substrate, and having an organic layer and an inorganic layer that are alternately stacked at least twice and a transition layer in which a ratio of an organic material to an inorganic material gradually varies; and
a display unit arranged on the first protective layer to display an image.

16. The display apparatus of claim 15, wherein the transition layer comprises:
a first transition layer, in which the ratio of the organic material to the inorganic material gradually decreases, formed at a first boundary between the organic layer and the inorganic layer, the organic and inorganic layers being positioned at lower and upper positions of the first boundary, respectively; and
a second transition layer, in which the ratio of the organic material to the inorganic material gradually increases, formed at a second boundary between the inorganic layer and the organic layer, the inorganic and organic layers being positioned at lower and upper positions of the second boundary, respectively.

17. The display apparatus of claim 16, wherein the inorganic layer comprises a composition of SiO₂, and the organic layer comprises a composition of SiOx(CH)yNz.

18. The display apparatus of claim 15, wherein the substrate comprises a plastic material.

19. The display apparatus of claim 15, further comprising a second protective layer covering the display unit and having a same layer structure as that of the first protective layer.

20. The display apparatus of claim 15, wherein the display unit comprises an electroluminance display device.

21. The display apparatus of claim 15, wherein the display unit comprises an organic thin-film transistor.
